(19) United States
(12) Patent Application Publication
(10) Pub. No.: US 2022/0013550 A1
(43) Pub. Date: Jan. 13, 2022

(54) PHOTODETECTOR

(71) Applicant: Panasonic Intellectual Property Management Co., Ltd., Osaka (JP)

(72) Inventors: Yuki SUGIURA, Osaka (JP); Akito INOUE, Osaka (JP)

(21) Appl. No.: 17/485,057

(22) Filed: Sep. 24, 2021

Related U.S. Application Data
(63) Continuation of application No. PCT/JP2020/011671, filed on Mar. 17, 2020.

(30) Foreign Application Priority Data
Mar. 29, 2019 (JP) 2019-067624

(51) Int. Cl. H01L 27/146

(52) U.S. Cl. CPC H01L 27/1461; H01L 27/14643; H01L 31/107; H01L 27/14627; H01L 27/14689; H01L 27/14625

(57) ABSTRACT

A photodetector includes: a pixel array in which a plurality of pixels are arranged in an array. Each of the plurality of pixels includes: a first semiconductor layer and a second semiconductor layer which are a first conductivity type, the second semiconductor layer located above the first semiconductor layer and having an impurity concentration lower than the impurity concentration of the first semiconductor layer; and a first semiconductor region, of a second conductivity type different from the first conductivity type, which is disposed in the second semiconductor layer and joined to the first semiconductor layer. The first semiconductor layer and the first semiconductor region constitute a multiplication region in which a charge is multiplied by avalanche multiplication. The pixel array includes a first separator of the first conductivity type disposed in the second semiconductor layer and a second separator of the first conductivity type disposed in the first semiconductor layer.

### CROSS REFERENCE TO RELATED APPLICATIONS

This is a continuation application of PCT International Application No. PCT/JP2020/011671 filed on Mar. 17, 2020, designating the United States of America, which is based on and claims priority of Japanese Patent Application No. 2019-067624 filed on Mar. 29, 2019. The entire disclosures of the above-identified applications, including the specifications, drawings and claims are incorporated herein by reference in their entirety.

### FIELD

The present disclosure relates to a photodetector, particularly to a photodetector capable of detecting faint light.

### BACKGROUND

In recent years, highly sensitive photodetectors have been used in a wide range of fields such as medical care, communications, biotechnology, chemistry, surveillance, in-vehicle use, and radiation detection. An avalanche photodiode (APD) is known as one of the highly sensitive photodetectors. An avalanche photodiode is a photodiode in which light detection sensitivity is enhanced by multiplying the signal charge generated by photoelectric conversion (avalanche multiplication) using avalanche breakdown.

### CITATION LIST

### Patent Literature

PTL 1: Japanese Unexamined Patent Application Publication No. H10-233525

PTL 2: International Patent Publication No. 2016/013170

PTL 3: Japanese Unexamined Patent Application Publication No. 2017-5276

PTL 4: Japanese Unexamined Patent Application Publication No. 2018-201005

### SUMMARY

### Technical Problem

The present disclosure provides a photodetector capable of improving photon detection efficiency.

### Solution to Problem

The photodetector according to one aspect of the present disclosure is A photodetector, including: a pixel array in which a plurality of pixels are arranged in an array; wherein each of the plurality of pixels includes: a first semiconductor layer of a first conductivity type; a second semiconductor layer of the first conductivity type located above the first semiconductor layer and having an impurity concentration lower than an impurity concentration of the first semiconductor layer; and a first semiconductor region of a second conductivity type disposed in the second semiconductor layer and joined to the first semiconductor layer, the second conductivity type being different from the first conductivity type, the first semiconductor layer and the first semiconductor region constitute a multiplication region in which a charge is multiplied by avalanche multiplication, and the pixel array includes a first separator of the first conductivity type disposed in the second semiconductor layer and a second separator of the first conductivity type disposed in the first semiconductor layer.

### Advantageous Effects

According to the present disclosure, the photon detection efficiency can be improved.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is an exploded perspective view of a photodetector according to Embodiment 1.

FIG. 2 is a plan view of the photodetector according to Embodiment 1.

FIG. 3 is an enlarged plan view of a pixel array according to Embodiment 1.

FIG. 4 is an enlarged cross-sectional view of the pixel array according to Embodiment 1.

FIG. 5 is a schematic diagram showing an example of a manufacturing procedure of the pixel array according to Embodiment 1.

FIG. 6A is a schematic diagram showing how electrons move in the pixel according to Embodiment 1.

FIG. 6B is a schematic diagram showing how electrons move in a pixel according to a comparative example.

FIG. 7A is a two-dimensional distribution diagram of the acceptor density in the cross section of the pixel according to Embodiment 1.

FIG. 7B is a two-dimensional distribution diagram of the acceptor density in the cross section of the pixel according to the comparative example.

FIG. 8A is a one-dimensional distribution diagram of the acceptor density in the cross section of the pixel according to Embodiment 1.

FIG. 8B is a one-dimensional distribution diagram of the acceptor density in the cross section of the pixel according to the comparative example.

FIG. 9A is a two-dimensional distribution diagram of the electrostatic potential in a cross section of the pixel according to Embodiment 1.

FIG. 9B is a two-dimensional distribution diagram of the electrostatic potential in a cross section of the pixel according to the comparative example.

FIG. 10 is a one-dimensional distribution diagram of electrostatic potentials in the cross section of the pixel according to Embodiment 1 and the cross section of the pixel according to the comparative example.

FIG. 11 is an enlarged cross-sectional view of the pixel array according to Variation 1.

FIG. 12 is an enlarged cross-sectional view of the pixel array according to Variation 2.

FIG. 13 is a plan view of the photodetector according to Embodiment 2.

FIG. 14 is an enlarged plan view of the pixel array according to Embodiment 2.

FIG. 15 is an enlarged cross-sectional view of the pixel array according to Embodiment 2.

FIG. 16 is an enlarged cross-sectional view of the pixel array according to Embodiment 2.

FIG. 17 is an enlarged plan view of the pixel array according to Variation 3.

FIG. 18 is an enlarged cross-sectional view of the pixel array according to Variation 3.

FIG. 19 is an enlarged cross-sectional view of the pixel array according to Variation 3.

FIG. 20 is an enlarged cross-sectional view of the pixel array according to Variation 4.

FIG. 21 is an enlarged cross-sectional view of the pixel array according to Variation 4.

### DESCRIPTION OF EMBODIMENTS

### Summary of the Present Disclosure

An avalanche photodiode that has a PN junction that generates a high electric field and uses avalanche multiplication is known as an element for increasing the sensitivity of photodetectors such as complementary metal-oxide-semiconductor (CMOS) image sensors (see, for example, Patent Literature (PTL) 1).

The separator of a conventional avalanche photodiode suppresses charge outflow after multiplication by electrically separating the pixel storage region, and suppresses the outflow of signal charges to the adjacent pixels and pixel circuits by being formed continuously from the surface side to the deep side of the pixel array. If the former storage region separation can be formed narrowly within the range where the electrical separation ability can be secured, the area ratio of the avalanche photodiode can be increased and the photon detection efficiency can be increased, and by forming the latter signal charge separator wider, it is possible to suppress the intrusion of signal charges into the low electric field region on the outer periphery of the avalanche photodiode and increase the photon detection efficiency. The present disclosure provides a pixel structure having a higher photon detection efficiency than the conventional one by forming a structure in which the separator is divided into two portions of a first separator on the surface side of the pixel array and a second separator on the deep side in a photodetector including a pixel array in which a plurality of pixels each having an avalanche photodiode are arranged in an array, and forming each of the separators into a structure suitable for improving the photon detection efficiency.

The photodetector according to one aspect of the present disclosure is a photodetector including a pixel array in which a plurality of pixels are arranged in an array, wherein each of the plurality of pixels includes: a first semiconductor layer of a first conductivity type; a second semiconductor layer of the first conductivity type located above the first semiconductor layer and having an impurity concentration lower than an impurity concentration of the first semiconductor layer; and a first semiconductor region of a second conductivity type disposed in the second semiconductor layer and joined to the first semiconductor layer, the second conductivity type being different from the first conductivity type, the first semiconductor layer and the first semiconductor region constitute a multiplication region in which a charge is multiplied by avalanche multiplication, and the pixel array includes a first separator of the first conductivity type disposed in the second semiconductor layer and a second separator of the first conductivity type disposed in the first semiconductor layer.

According to the photodetector having the above configuration, the first separator and the second separator can be formed at positions where the electrical influence on the joint surface between the second semiconductor layer and the first semiconductor region is relatively small. For this reason, it is possible to suppress the limitation of the area of the multiplication region in each pixel due to the electric influence from the first separator and the second separator. Therefore, according to the photodetector having the above configuration, the photon detection efficiency can be improved.

In addition, the second separator may have an impurity concentration higher than an impurity concentration of a region of the first semiconductor layer which is of a same depth as the second separator and where the second separator is not disposed.

With this, the signal charge generated by the photoelectric conversion in the first semiconductor layer of one pixel can be more reliably guided to the multiplication region of that one pixel. For this reason, according to the photodetector having the above configuration, the photon detection efficiency can be further improved.

In addition, in a plan view of the pixel array, the second separator may overlap at least part of the first semiconductor region in each of the plurality of pixels.

With this, the signal charge generated by the photoelectric conversion in the first semiconductor layer of one pixel can be more reliably guided to the multiplication region of that one pixel. For this reason, according to the photodetector having the above configuration, the photon detection efficiency can be further improved.

In addition, in a plan view of the pixel array, the second separator may not overlap at least part of a uniform electric field region included in the first semiconductor region in each of the plurality of pixels, the uniform electric field region being a region in which an electric field is uniform.

This makes it possible to suppress variations in the multiplication amplitude between pixels.

In addition, the impurity concentration of the first semiconductor layer may be high on an upper side where the multiplication region is included, and the impurity concentration on a lower side of the first semiconductor layer may be lower than or equal to the impurity concentration on the upper side.

In the photodetector having the above configuration, a potential gradient from the upper side to the lower side is formed in the depletion layer formed in the first semiconductor layer. By forming this depletion layer to a relatively deep part of the first semiconductor layer, the drift velocity of the signal charge generated by photoelectric conversion in the first semiconductor layer from the lower side to the upper side increases due to the potential gradient. For this reason, according to the photodetector having the above configuration, the photon detection efficiency can be further improved.

In addition, the impurity concentration of the first semiconductor layer may increase from an upper side to a lower side of the first semiconductor layer.

In the photodetector having the above configuration, a gradient of the built-in potential is formed in the region where the depletion layer is not formed in the first semiconductor layer. The drift velocity of the signal charge generated by the photoelectric conversion in the first semiconductor layer from the lower side to the upper side increases due to the gradient of the built-in potential. With this, according to the photodetector having the above configuration, even if the depletion layer formed in the first semiconductor layer is not formed in a relatively deep part of the first semiconductor layer, that is, even if no relatively large voltage is applied to the first semiconductor layer, the photon detection efficiency can be further improved.

In addition, the pixel may include a circuit region disposed in the second semiconductor layer, the circuit region including one or more transistors, and the second separator may overlap at least part of the circuit region in a plan view of the pixel array.

With this, it is possible to suppress the entry of the signal charge generated by the photoelectric conversion in the first semiconductor layer into the circuit region.

In addition, the second separator may have a cross section parallel to the pixel array extending from an upper side to a lower side of the first semiconductor layer.

With this, the signal charge generated by the photoelectric conversion in the first semiconductor layer of one pixel can be guided to the multiplication region of that one pixel while the electrical influence of the second separator on the junction surface between the second semiconductor layer and the first semiconductor region is suppressed. For this reason, according to the photodetector having the above configuration, the photon detection efficiency can be further improved.

In addition, the second separator may have a cross section parallel to the pixel array extending from a lower side to an upper side of the first semiconductor layer.

With this, even if the effective multiplication region is narrowed, the photon detection efficiency is not reduced. For this reason, according to the photodetector having the above configuration, the photodiode can be made small.

Hereinafter, a specific example of the photodetector according to one aspect of the present disclosure will be described with reference to the drawings. It should be noted that all of the embodiments described below show comprehensive or specific examples. The numerical values, shapes, materials, components, arrangement positions and connection forms of the components, and the like shown in the following embodiments are examples, and are not intended to limit the present disclosure. In addition, among the components in the following embodiments, the components not described in the independent claims indicating the broadest concept are described as arbitrary components.

It should be noted that each figure is a schematic diagram and is not necessarily exactly illustrated. In addition, in each figure, substantially the same configuration is designated by the same reference numerals, and duplicate description may be omitted or simplified.

In addition, coordinate axes may be shown in the drawings used for the description in the following embodiments. The Z-axis direction in the coordinate axes is, for example, the vertical direction, the Z-axis+side is expressed as the upper side (upward), and the Z-axis-side is expressed as the lower side (downward). In other words, the Z-axis direction is a direction perpendicular to the upper surface or the lower surface of the semiconductor substrate, and is a thickness direction of the semiconductor substrate. In addition, the X-axis direction and the Y-axis direction are directions orthogonal to each other on a plane (horizontal plane) perpendicular to the Z-axis direction. The X-axis direction is expressed as the horizontal direction, and the Y-axis direction is expressed as the vertical direction. In the following embodiments, “in a plan view” means viewing from the Z-axis direction. In addition, the present disclosure does not exclude the structure in which the P-type and the N-type are reversed in the following embodiments.

### Embodiment 1

Hereinafter, the photodetector according to Embodiment 1 will be described with reference to the drawings.

### 1-1. Configuration

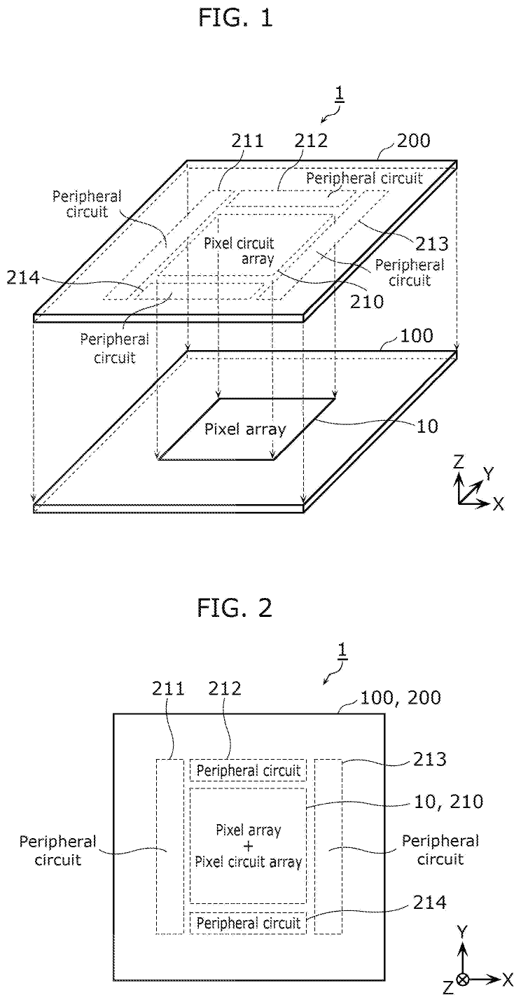

FIG. 1 is an exploded perspective view of photodetector 1 according to Embodiment 1. FIG. 2 is a plan view of photodetector 1 according to Embodiment 1. In FIG. 1 and FIG. 2, some of the elements that cannot be directly visually recognized are shown by broken lines as if they were visible.

As shown in FIG. 1 and FIG. 2, photodetector 1 is configured by joining the surface of flipped second semiconductor chip 200 to the surface of first semiconductor chip 100.

First semiconductor chip 100 includes pixel array 10 in which a plurality of pixels including avalanche photodiodes are arranged in an array. Photons are incident on each avalanche photodiode from the back surface of first semiconductor chip 100. When a photon (for example, a photon having an infrared wavelength region) is incident, each avalanche photodiode generates a signal charge corresponding to the incident photon. In other words, each pixel included in pixel array 10 generates a signal charge corresponding to a photon incident from the back surface of first semiconductor chip 100. Pixel array 10 does not include a logic circuit.

Second semiconductor chip 200 includes pixel circuit array 210 in which a plurality of pixel circuits corresponding to a plurality of pixels included in pixel array 10 on a one-to-one basis are arranged in an array, and peripheral circuit 211 to peripheral circuit 214.

Pixel circuit array 210 is joined to pixel array 10 so that each of the pixel circuits included in pixel circuit array 210 is joined to a corresponding one of the pixels on a one-to-one basis.

The respective pixel circuits and peripheral circuit 211 to peripheral circuit 214 are configured to include logic circuits, and read out signal charges from the respective pixels included in pixel array 10a by operating in synchronization with one another.

With the above configuration, photodetector 1 functions as, for example, a solid-state image sensor.

Hereinafter, the pixels included in pixel array 10 will be described with reference to the drawings.

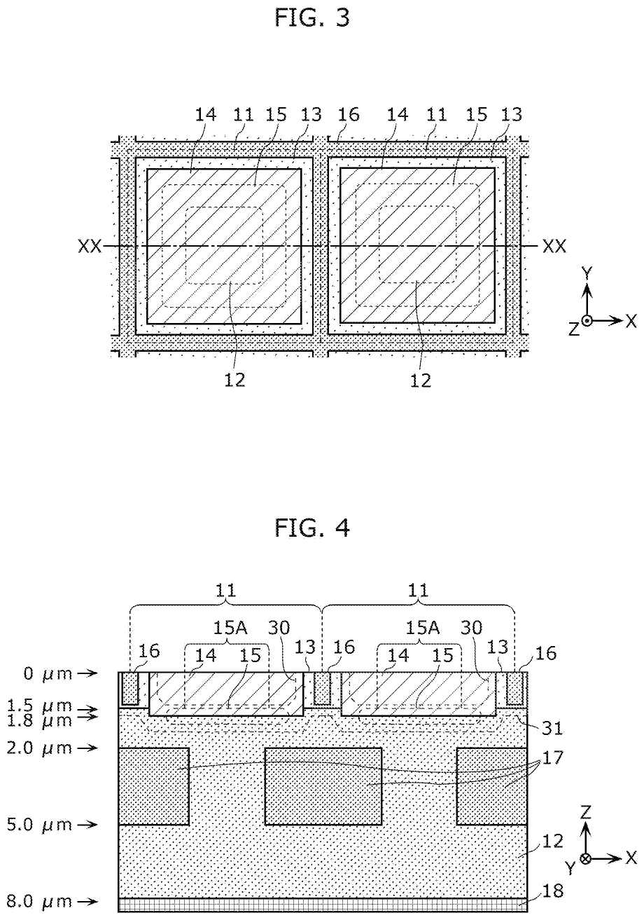

FIG. 3 is an enlarged plan view of pixel array 10. FIG. 4 is an enlarged cross-sectional view of pixel array 10 in the case where pixel array 10 is cut along the XX-XX line in FIG. 3. In FIG. 3, some of the elements that cannot be directly visually recognized are shown by broken lines as if they could be visually recognized.

As shown in FIG. 3 and FIG. 4, each pixel 11 included in pixel array 10 is configured to include first semiconductor layer 12, second semiconductor layer 13, first semiconductor region 14, first separator 16, second separator 17, and semiconductor substrate 18.

Semiconductor substrate 18 is a silicon substrate of a first conductivity type (here, for example, P type). The impurity concentration of semiconductor substrate 18 is, for example, 1×10¹⁸ to 1×10²⁰ cm⁻³. Semiconductor substrate 18 is ground by, for example, a back grinding to a thickness of, for example, 100 nm to 200 nm.

First semiconductor layer 12 is a semiconductor layer of a first conductivity type located above semiconductor substrate 18. The impurity concentration of first semiconductor layer 12 is, for example, 1×10¹⁶ to 1×10¹⁸ cm⁻³. For example, the upper surface of first semiconductor layer 12 is located at a depth of 1.5 μm from the surface of first semiconductor chip 100, and the lower surface thereof is located at a depth of 8.0 μm from the surface of first semiconductor chip 100. First semiconductor layer 12 is formed, for example, by performing epitaxial growth on semiconductor substrate 18. The impurity concentration of first semiconductor layer 12 increases from the upper side to the lower side. With this, the drift velocity of the charges (also referred to as charged particles, here, for example, electrons) of the minority carriers in first semiconductor layer 12 from the lower side to the upper side increases.

Second semiconductor layer 13 is a semiconductor layer of a first conductivity type located above semiconductor substrate 18. The impurity concentration of second semiconductor substrate 13 is, for example, 1×10¹⁴ to 1×10¹⁵ cm⁻³. For example, the upper surface of second semiconductor layer 13 is located on the surface of first semiconductor chip 100, and the lower surface thereof is located at a depth of 1.5 μm from the surface of first semiconductor chip 100. Second semiconductor layer 13 is formed, for example, by performing epitaxial growth on first semiconductor layer 12.

First semiconductor region 14 is a region of a second conductivity type (here, for example, N type), which is different from the first conductivity type, formed in second semiconductor layer 13 and joined to first semiconductor layer 12. The impurity concentration of first semiconductor region 14 is, for example, 5×10¹⁶ to 1×10¹⁹ cm⁻³. For example, the upper surface of first semiconductor region 14 is located on the surface of first semiconductor chip 100, and the lower surface thereof is located at a depth of 1.8 μm from the surface of first semiconductor chip 100. As shown in FIG. 4, first semiconductor region 14 may penetrate the lower surface of second semiconductor layer 13 and protrude into first semiconductor layer 12. First semiconductor region 14 is formed, for example, by injecting second conductivity type impurity (for example, arsenic) ions accelerated at a voltage in a desired range from the surface of second semiconductor layer 13.

By applying a predetermined first voltage (for example, 27 V) between semiconductor substrate 18 and first semiconductor region 14, first semiconductor layer 12 and first semiconductor region 14 form multiplication region 15 in which charges are multiplied by avalanche multiplication. First semiconductor region 14 accumulates charges multiplied by the avalanche multiplication.

In multiplication region 15, the electric field becomes non-uniform in the outer edge region of pixel array 10 in a plan view. For this reason, from the viewpoint of suppressing the variation in the amount of charge to be multiplied in multiplication region 15, it is desirable that the charge to be multiplied is multiplied in electric field uniform region 15A, which is a region in which the electric field is uniformly formed, excluding the outer edge region, in multiplication region 15.

A depletion layer is formed around the junction surface between first semiconductor region 14 and first semiconductor layer 12 and around the junction surface between first semiconductor region 14 and second semiconductor layer 13. In FIG. 4, the depletion layer formed in a state where the first voltage is applied between semiconductor substrate 18 and first semiconductor region 14 is illustrated as a region between upper layer side depletion layer end 30 and lower layer side depletion layer end 31.

First separator 16 is a first conductivity type region which is formed in second semiconductor layer 13 and electrically separates pixels 11 adjacent to each other. The impurity concentration of first separator 16 is, for example, 1×10¹⁶ to 1×10¹⁸ cm⁻³. For example, the upper surface of first separator 16 is located on the surface of first semiconductor chip 100, and the lower surface thereof is located at a depth of 1.5 μm from the surface of first semiconductor chip 100. First separator 16 is formed, for example, by injecting first conductivity type impurity (for example, boron) ions accelerated at a voltage in a desired range from the surface of second semiconductor layer 13.

Second separator 17 is a first conductivity type region which is formed in first semiconductor layer 12 and electrically separates pixels 11 adjacent to each other. The impurity concentration of second separator 17 is, for example, 1×10¹⁶ to 1×10¹⁸ cm⁻³. The impurity concentration of second separator 17 is three times or more higher than the surrounding impurity concentration. For example, the upper surface of second separator 17 is located at a depth of 2.0 μm from the surface of first semiconductor chip 100, and the lower surface thereof is located at a depth of 5.0 μm from the surface of first semiconductor chip 100. Second separator 17 overlaps at least part of multiplication region 15 in a plan view of pixel array 10. Then, second separator 17 does not overlap with at least part of electric field uniform region 15A in a plan view of pixel array 10. Second separator 17 is formed, for example, by injecting first conductivity type impurity (for example, boron) ions accelerated at a voltage in a desired range from the surface of second semiconductor layer 13.

It should be noted that photodetector 1 may have such a configuration that a plurality of micro lenses that focus light incident from the outside of first semiconductor chip 100 are arranged in an array on the back surface of semiconductor substrate 18, that is, the back surface of first semiconductor chip 100, and the light focused by each micro lens is incident on each pixel 11.

### 1-2. Manufacturing Method

Hereinafter, the manufacturing method of pixel array 10 will be described with reference to the drawings.

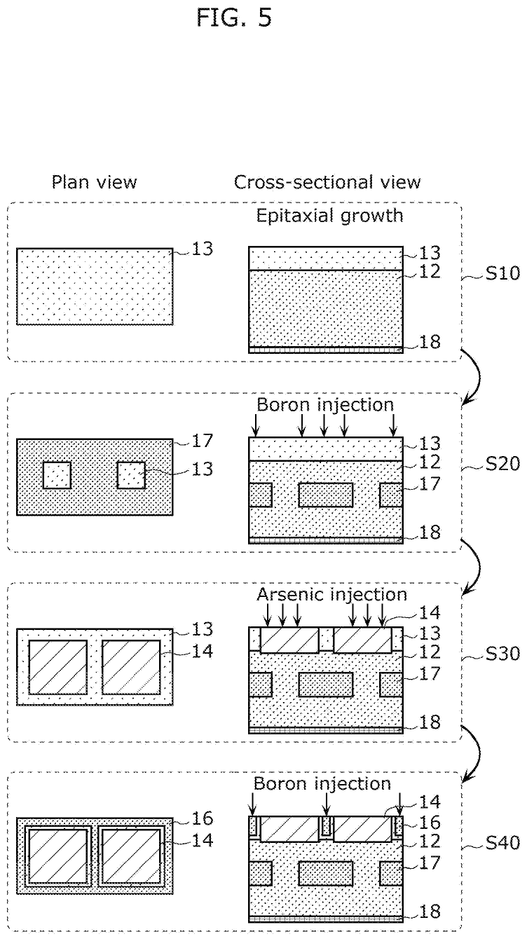

FIG. 5 is a schematic diagram showing an example of a manufacturing procedure of pixel array 10.

As shown in FIG. 5, the manufacturing device for manufacturing pixel array 10 first forms first semiconductor layer 12 by performing epitaxially growth on semiconductor substrate 18. Then, the manufacturing device forms second semiconductor layer 13 by performing epitaxial growth on the formed first semiconductor layer 12 (step S10).

Next, the manufacturing device forms second separator 17 by injecting first conductivity type impurity (for example, boron) ions accelerated at a voltage in a desired range from the surface of second semiconductor layer 13 into a desired region (step S20).

Next, the manufacturing device forms first semiconductor region 14 by injecting second conductivity type impurity (for example, arsenic) ions accelerated at a voltage in a desired range from the surface of second semiconductor layer 13 into a desired region (step S30).

Finally, the manufacturing device forms first separator 16 by injecting first conductivity type impurity (for example, boron) ions accelerated at a voltage in a desired range from the surface of second semiconductor layer 13 into a desired region (step S40).

### 1-3. Consideration

According to photodetector 1 having the above configuration, first separator 16 and second separator 17 can be arranged to be separated from each other. With this, first separator 16 and second separator 17 can be formed to be separated from each other at positions where the electrical influence on the joint surface between second semiconductor layer 13 and first semiconductor region 14 is relatively small. For this reason, it is possible to suppress the limitation of the area of multiplication region 15 in each pixel 11 due to the electrical influence from first separator 16 and second separator 17. Therefore, according to photodetector 1, the photon detection efficiency can be improved.

According to photodetector 1, second separator 17 overlaps at least part of multiplication region 15 in a plan view of pixel array 10. With this, it is possible to suppress such a phenomenon (hereinafter, also referred to as “first phenomenon”) that the charges generated by the photoelectric effect in first semiconductor layer 12 of one pixel 11 are accumulated in first semiconductor region 14 of one pixel 11, and such a phenomenon (hereinafter, also referred to as “second phenomenon”) that they are accumulated in first semiconductor region 14 of other adjacent pixels 11, without passing through multiplication region 15. For this reason, the signal charge generated by the photoelectric conversion in first semiconductor layer 12 of one pixel 11 can be more reliably guided to multiplication region 15 of that one pixel 11. Therefore, according to photodetector 1, the photon detection efficiency can be further improved.

Hereinafter, the reason why the first phenomenon and the second phenomenon are suppressed in photodetector 1 will be described with reference to the drawings.

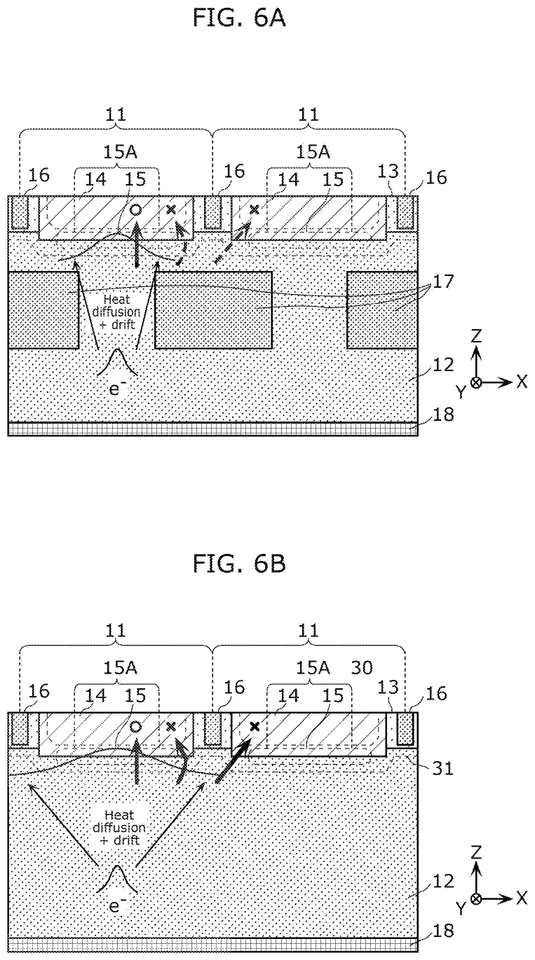

FIG. 6A is a schematic view showing how electrons, which are minority carriers generated in first semiconductor layer 12 below multiplication region 15 by photoelectric conversion, move by heat diffusion and drift in pixel 11.

FIG. 6B is a schematic showing how electrons, which are minority carriers generated in first semiconductor layer 12 below multiplication region 15 by photoelectric conversion, move by heat diffusion and drift in the pixel according to the comparative example. Here, the pixel according to the comparative example is a pixel configured so that second separator 17 is not formed with respect to pixel 11 according to Embodiment 1.

In the pixel according to the comparative example, the electrons generated in first semiconductor layer 12 below multiplication region 15 drift from the lower side to the upper side of first semiconductor layer 12 (that is, to the positive side in the Z axis direction) due to the gradient of the impurity concentration in first semiconductor layer 12. At the same time, the electrons are heat diffused in the plane direction of first semiconductor layer 12 (that is, in the plane direction including the X-axis direction and the Y-axis direction). For this reason, a part of the electrons generated in first semiconductor layer 12 below multiplication region 15 is heat diffused from the inside to the outside of multiplication region 15 in a plan view of the pixel array according to the comparative example while drifting from the lower side to the upper side of first semiconductor layer 12. Then, a part of the electrons heat diffused to the outside of multiplication region 15 in a plan view penetrates into first semiconductor region 14 without passing through multiplication region 15, and thereby, the first phenomenon occurs. In addition, a part of the electrons heat diffused to the outside of multiplication region 15 in a plan view further heat diffuses to the adjacent pixels, and thereby, the second phenomenon occurs.

On the other hand, in pixel 11 according to Embodiment 1, the electrons generated in first semiconductor layer 12 below multiplication region 15 drift from the lower side to the upper side of first semiconductor layer 12 in the same manner as the pixel according to the comparative example, and heat diffuse in the plane direction of first semiconductor layer 12. However, the range of the heat diffusion is limited to the range surrounded by second separator 17 in a plan view of pixel array 10. For this reason, the heat diffusion of the electrons generated in first semiconductor layer 12 below multiplication region 15 to the outside of multiplication region 15 in a plan view when drifting from the lower side to the upper side of first semiconductor layer 12 is suppressed. Therefore, in photodetector 1, the first phenomenon and the second phenomenon are suppressed.

Hereinafter, in pixel 11, the reason why the heat diffusion to the outside of multiplication region 15 in a plan view when the electrons generated in first semiconductor layer 12 below multiplication region 15 drift from the lower side to the upper side of first semiconductor layer 12 is suppressed will be described with reference to the drawings.

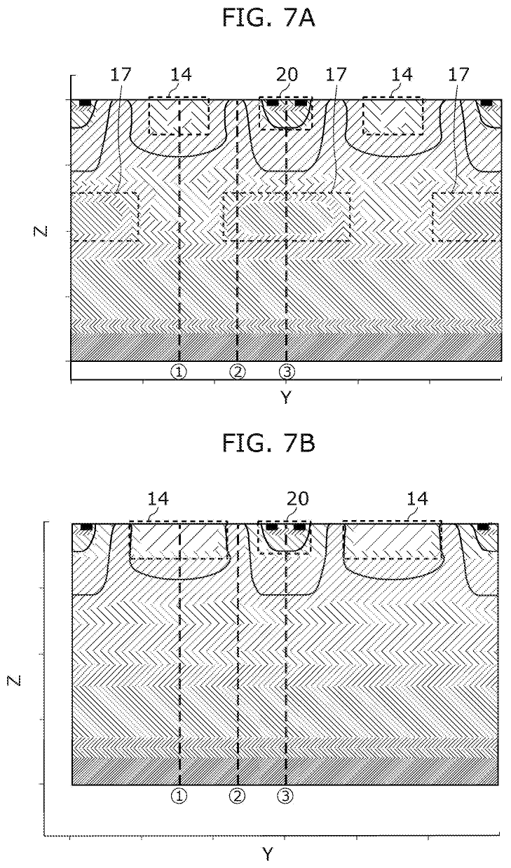

FIG. 7A is a two-dimensional distribution diagram of the acceptor density (impurity concentration) in the cross section of pixel 11.

FIG. 7B is a two-dimensional distribution diagram of the acceptor density in the cross section of the pixel according to the comparative example.

In FIG. 7A and FIG. 7B, the acceptor density is shown by the shade of the hatching so that the higher the acceptor density, the darker the hatching.

Here, the two-dimensional distribution diagram of the acceptor density shown in FIG. 7A is, to be precise, a two-dimensional distribution diagram of the acceptor density in a cross section of a pixel “hereinafter, also referred to as “pixel A”” having a different configuration from pixel 11 in that it includes circuit region 20 in which a pixel circuit is formed. However, whether the pixel includes circuit region 20 does not affect the following description, so that here, the two-dimensional distribution diagram of the acceptor density shown in FIG. 7A is intentionally described as a two-dimensional distribution diagram of the acceptor density in the cross section of pixel 11. In addition, the two-dimensional distribution diagram of the acceptor density shown in FIG. 7B is, to be exact, a two-dimensional distribution diagram of the acceptor density in a cross section of a pixel “hereinafter, also referred to as “pixel B”” having a different configuration from a pixel according to the comparative example in that it includes circuit region 20. However, whether the pixel includes circuit region 20 does not affect the following description, so that here, the two-dimensional distribution diagram of the acceptor density shown in FIG. 7B is intentionally described as a two-dimensional distribution diagram of the acceptor density in the cross section of the pixel according to the comparative example.

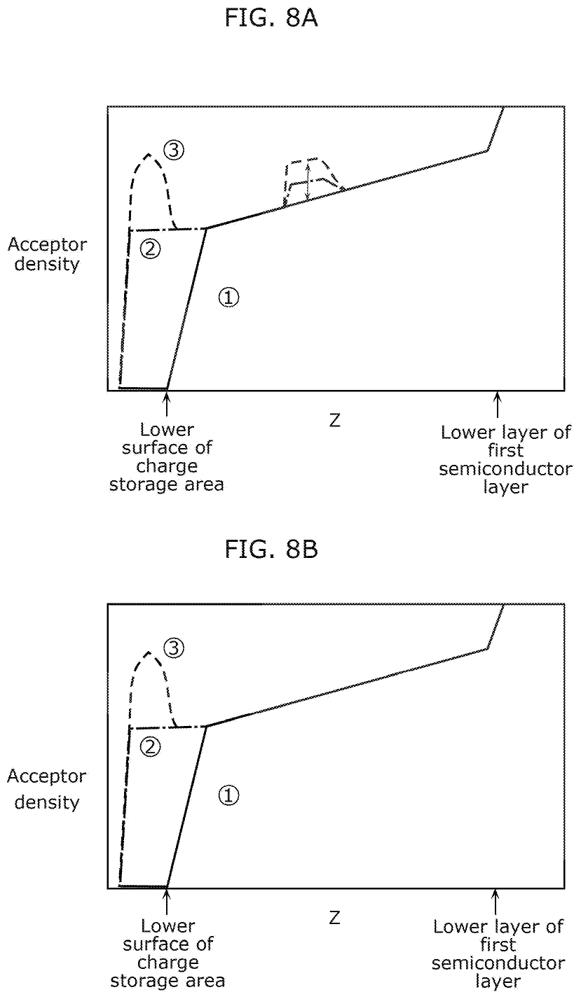

FIG. 8A is a one-dimensional distribution diagram of the acceptor density in the cross section of pixel 11, and is a diagram in which the acceptor densities at the positions of the broken line “1”, the broken The “2”, and the broken line “3” in FIG. 7A are plotted.

FIG. 8B is a one-dimensional distribution diagram of the acceptor density in the cross section of the pixel according to the comparative example, and is a diagram in which the acceptor densities at the positions of the broken line “1”, the broken line “2”, and the broken The “3” in FIG. 7B are plotted.

Here, the one-dimensional distribution diagram of the acceptor density shown in FIG. 8A is, to be exact, a one-dimensional distribution diagram of the acceptor density in the cross section of pixel A. However, for the same reason as in the case of FIG. 7A, the one-dimensional distribution diagram of the acceptor density shown in FIG. 8A will be intentionally described as a one-dimensional distribution diagram of the acceptor density in the cross section of pixel 11. In addition, the one-dimensional distribution diagram of the acceptor density shown in FIG. 8B is, to be exact, a one-dimensional distribution diagram of the acceptor density in the cross section of pixel B. However, for the same reason as in the case of FIG. 7B, the one-dimensional distribution diagram of the acceptor density shown in FIG. 8B will be intentionally described as a one-dimensional distribution diagram of the acceptor density in the cross section of the pixel according to the comparative example.

As shown in FIG. 7B and FIG. 8B, in the pixel according to the comparative example, there is no gradient of acceptor density in the plane direction of first semiconductor layer 12 in the region of first semiconductor layer 12 from the lower surface of first semiconductor region 14 to the lower surface of first semiconductor layer 12. For this reason, the heat diffusion of electrons in the plane direction of first semiconductor layer 12 is not suppressed.

On the other hand, as shown in FIG. 7A and FIG. 8A, in pixel 11, the acceptor density of the region where second separator 17 is formed is three times as high as that of the surroundings in the region of first semiconductor layer 12, ranging from the lower surface of first semiconductor region 14 to the lower surface of first semiconductor layer 12. The heat diffusion of electrons in the plane direction of first semiconductor layer 12 into the region where the acceptor density is three times higher than the surroundings, that is, the heat diffusion of electrons in the plane direction of first semiconductor layer 12 into second separator 17 is suppressed.

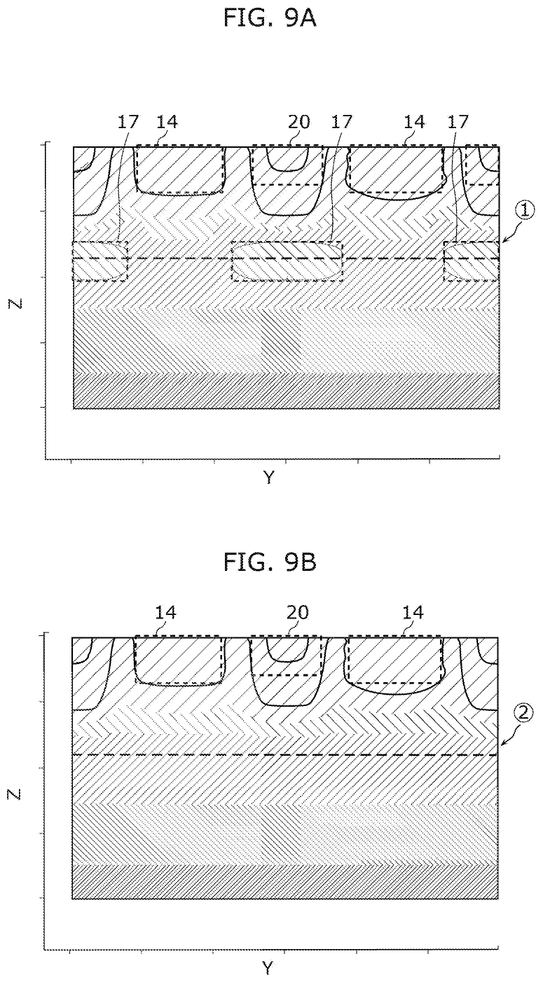

FIG. 9A is a two-dimensional distribution diagram of the electrostatic potential in the cross section of pixel 11.

FIG. 9B is a two-dimensional distribution diagram of the electrostatic potential in the cross section of the pixel according to the comparative example.

In FIG. 9A and FIG. 9B, high and low of the electrostatic potential is shown by the shade of the hatching so that the higher the electrostatic potential, the darker the hatching.

Here, the two-dimensional distribution diagram of the electrostatic potential shown in FIG. 9A is, to be exact, a two-dimensional distribution diagram of the electrostatic potential in the cross section of pixel A. However, whether the pixel includes circuit region 20 does not affect the following description, so that here, the two-dimensional distribution diagram of the electrostatic potential shown in FIG. 9A is intentionally described as a two-dimensional distribution diagram of the electrostatic potential in the cross section of pixel 11. In addition, the two-dimensional distribution diagram of the electrostatic potential shown in FIG. 9B is, to be exact, a two-dimensional distribution diagram of the electrostatic potential in the cross section of the pixel according to the comparative example. However, whether the pixel includes circuit region 20 does not affect the following description, so that here, the two-dimensional distribution diagram of the electrostatic potential shown in FIG. 9B is intentionally described as a two-dimensional distribution diagram of the electrostatic potential in the cross section of the pixel of the comparative example.

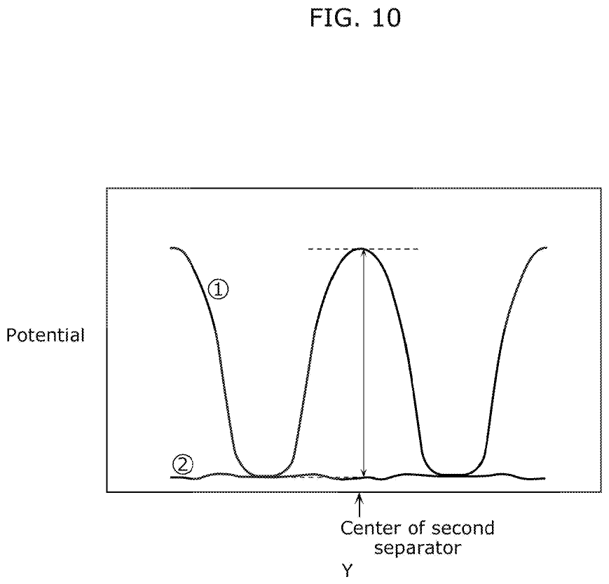

FIG. 10 is a diagram showing a plot of the electrostatic potential at the position of the broken line “1” in FIG. 9A, which is a one-dimensional distribution diagram of the electrostatic potential in the cross section of pixel 11, and a plot of the electrostatic potential at the position of the broken The “2” in FIG. 9B, which is a one-dimensional distribution diagram of the electrostatic potential in the cross section of the pixel according to the comparative example, superimposed.

As shown in FIG. 9A and FIG. 10, in pixel 11, a barrier of electrostatic potential, which is higher than 25.85 mV that is the thermal voltage of silicon at 300 K, in the plane direction of first semiconductor layer 12 is formed in the region where second separator 17 is formed. For this reason, in pixel 11, the heat diffusion of the electrons in the plane direction of first semiconductor layer 12 into the region where second separator 17 is formed is suppressed. On the other hand, as shown in FIG. 9B and FIG. 10, in the pixel according to the comparative example, the barrier of the electrostatic potential due to the formation of second separator 17 is not formed. For this reason, in the pixel according to a variation, the heat diffusion of the electrons in the plane direction of first semiconductor layer 12 is not suppressed.

For the above reason, the first phenomenon and the second phenomenon are suppressed in photodetector 1.

It should be noted that in order to form a barrier having an electrostatic potential higher than 25.85 mV that is the thermal voltage of silicon at 300 K, the acceptor density (impurity concentration) of second separator 17 is only needed to be three times or more higher than that of the surroundings.

According to photodetector 1, second separator 17 does not overlap at least part of electric field uniform region 15A in a plan view of pixel array 10. With this, at least part of the electric charge generated by the photoelectric effect in first semiconductor layer 12 in each pixel 11 and diffused outside the electric field uniform region is avalanche multiplied in electric field uniform region 15A. Therefore, according to photodetector 1, it is possible to suppress variations in the multiplication amplitude among pixels 11.

### Variation 1

Hereinafter, the photodetector according to Variation 1 which is configured by modifying a part of the configuration from photodetector 1 according to Embodiment 1 will be described.

### 2-1. Configuration

The photodetector according to Variation 1 is configured by changing first semiconductor layer 12 from photodetector 1 to the first semiconductor layer according to Variation 1. Then, along with this change, pixel 11 is changed to the pixel according to Variation 1, and pixel array 10 is changed to the pixel array according to Variation 1.

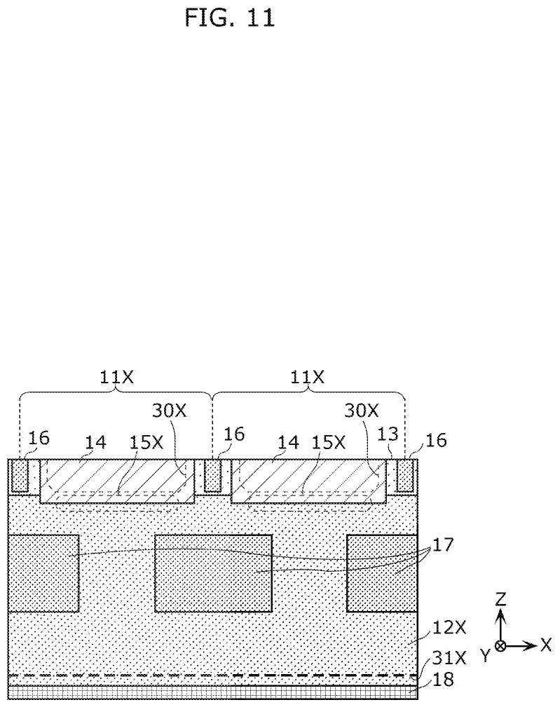

FIG. 11 is an enlarged cross-sectional view of the pixel array according to Variation 1. In the following, with respect to the photodetector according to Variation 1, since the same components as photodetector 1 have already been described, the same reference numerals are given to omit the detailed description thereof, and the difference from photodetector 1 will be mainly described.

As shown in FIG. 11, each pixel 11X included in the pixel array according to Variation 1 is configured by changing first semiconductor layer 12 to first semiconductor layer 12X from pixel 11 according to Embodiment 1.

First semiconductor layer 12X has been changed so that the gradient of the impurity concentration from the upper side to the lower side disappears from first semiconductor layer 12. For this reason, in first semiconductor layer 12X, unlike first semiconductor layer 12, there is no increase in the drift velocity of the charge of the minority carriers from the lower side to the upper side due to the gradient of the impurity concentration.

By applying a predetermined second voltage (for example, 50 V) between semiconductor substrate 18 and first semiconductor region 14, first semiconductor layer 12 and first semiconductor region 14 form multiplication region 15X in which charges are multiplied by avalanche multiplication.

A depletion layer is formed around the junction surface between first semiconductor region 14 and first semiconductor layer 12X and around the junction surface between first semiconductor region 14 and second semiconductor layer 13. In FIG. 11, the depletion layer formed in a state where the second voltage is applied between semiconductor substrate 18 and first semiconductor region 14 is illustrated as a region between upper layer side depletion layer end 30X and lower layer side depletion layer end 31X. As shown in FIG. 11, the depletion layer is formed so as to extend to the vicinity of semiconductor substrate 18 in first semiconductor layer 12X.

### 2-2. Consideration

According to the photodetector according to Variation 1 of the above configuration, in the region of first semiconductor layer 12X where the depletion layer from the junction surface with first semiconductor region 14 to the vicinity of semiconductor substrate 18 is formed, an electric field from the lower side to the upper side is formed. Then, this electric field increases the drift velocity of the charges of the minority carriers in first semiconductor layer 12X from the lower side to the upper side. In this way, the gradient of the electric field of the depletion layer formed in first semiconductor layer 12X acts on the charge drift of the minority carriers in first semiconductor layer 12X in the same manner as the gradient of the impurity concentration in first semiconductor layer 12.

Therefore, the photodetector according to Variation 1 can obtain the same effect as photodetector 1 according to Embodiment 1.

### Variation 2

Hereinafter, the photodetector according to Variation 2, which is configured by modifying a part of the configuration from photodetector 1 according to Embodiment 1, will be described.

### 3-1. Configuration

The photodetector according to Variation 2 is configured by changing second separator 17 from photodetector 1 to the second separator according to Variation 2. Then, along with this change, pixel 11 is changed to the pixel according to Variation 2, and pixel array 10 is changed to the pixel array according to Variation 2.

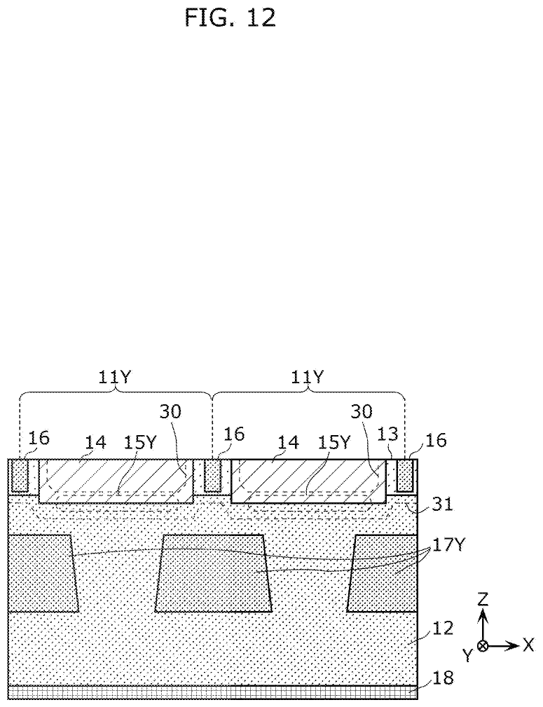

FIG. 12 is an enlarged cross-sectional view of the pixel array according to Variation 2. In the following, with respect to the photodetector according to Variation 2, since the same components as photodetector 1 have already been described, the same reference numerals are given to omit the detailed description thereof, and the difference from photodetector 1 will be mainly described.

As shown in FIG. 12, each pixel 11Y included in the pixel array according to Variation 2 is configured by changing second separator 17 to second separator 17Y from pixel 11 according to Embodiment 1.

The shape of second separator 17Y is changed from that of second separator 17. More specifically, second separator 17Y has a cross section parallel to the pixel array according to Variation 2, extending from the upper side to the lower side.

### 3-2. Consideration

According to the photodetector according to Variation 2 of the above configuration, the separation width of the upper surface of second separator 17Y can be narrowed in order to maintain the electric field uniformity of multiplication region 15, and the separation width of the lower surface of second separator 17Y can be widened in order to increase the electrical separation capacity with adjacent pixel 11Y.

Therefore, the photodetector according to Variation 2 can further improve the photon detection efficiency as compared with photodetector 1 according to Embodiment 1.

### Embodiment 2

Hereinafter, the photodetector according to Embodiment 2, which is configured by changing a part of the configuration from photodetector 1 according to Embodiment 1, will be described.

### 4-1. Configuration

Photodetector 1 according to Embodiment 1 was an example configured by joining the surface of flipped second semiconductor chip 200 on which a logic circuit is formed to the surface of first semiconductor chip 100 on which an avalanche photodiode is formed.

On the other hand, the photodetector according to Embodiment 2 is an example configured by forming an avalanche photodiode and a logic circuit on one semiconductor chip.

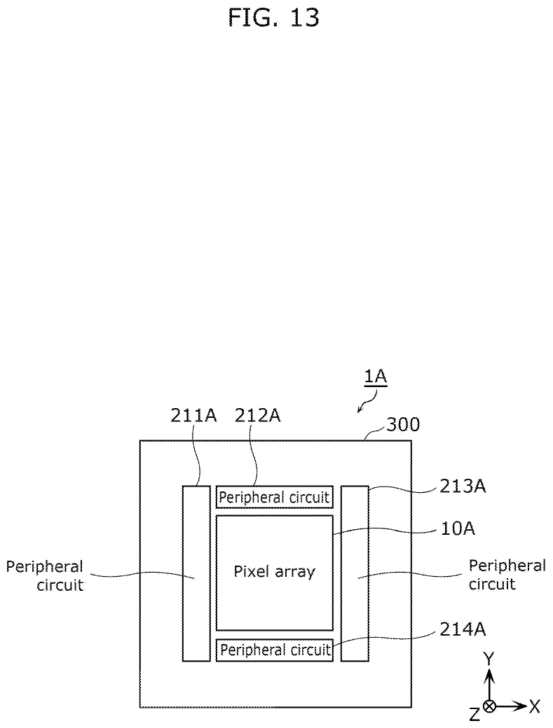

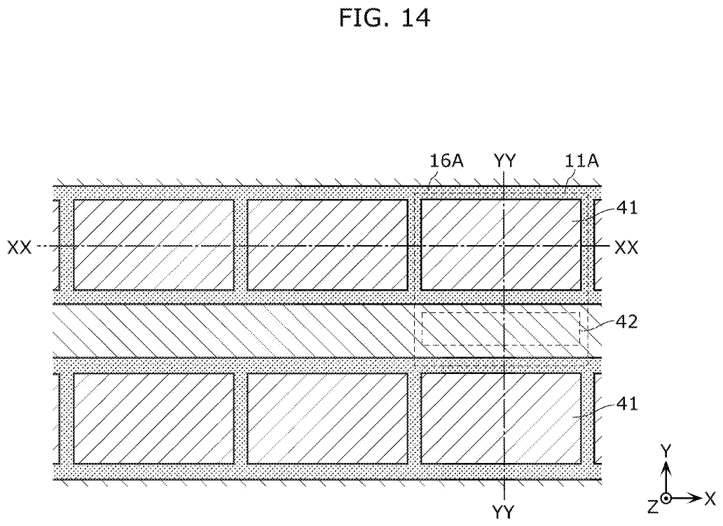

FIG. 13 is a plan view of photodetector 1A according to Embodiment 2.

As shown in FIG. 13, photodetector 1A includes third semiconductor chip 300 including pixel array 10A and peripheral circuits 211A to 214A.

Pixel array 10A is configured by arranging a plurality of pixels in an array, each of which includes a photodiode region in which an avalanche photodiode is formed and a circuit region in which a pixel circuit is formed. Photons are incident on each avalanche photodiode from the surface of third semiconductor chip 300. When a photon (for example, a photon having an infrared wavelength region) is incident, each avalanche photodiode generates a signal charge corresponding to the incident photon. In other words, the photodiode region of each pixel included in pixel array 10A generates a signal charge corresponding to photons incident from the surface of third semiconductor chip 300.

Peripheral circuit 211A to peripheral circuit 214A are configured to include logic circuits and read out signal charges from the photodiode region of each pixel by operating in synchronization with the circuit region of each pixel.

With the above configuration, photodetector 1A functions as, for example, a solid-state image sensor.

Hereinafter, the pixels included in pixel array 10A will be described with reference to the drawings.

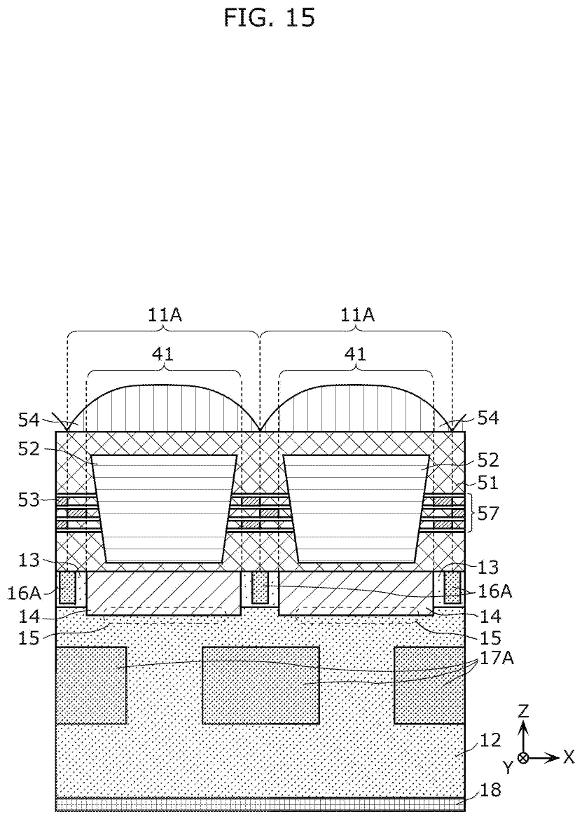

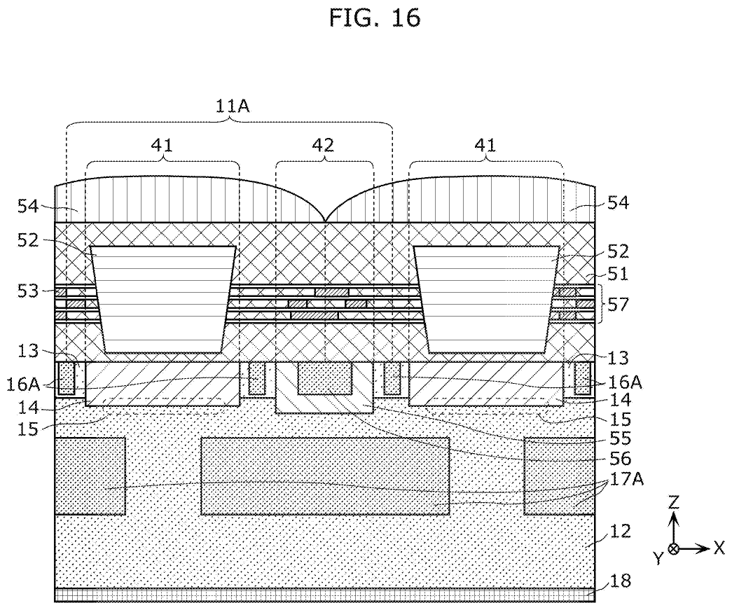

FIG. 14 is an enlarged plan view of pixel array 10A. FIG. 15 is an enlarged cross-sectional view of pixel array 10A in the case where pixel array 10A is cut along the XX-XX line of FIG. 14. FIG. 16 is an enlarged cross-sectional view of pixel array 10A in the case where pixel array 10A is cut along the YY-YY line of FIG. 14. Here, in order to make the drawings easier to see, FIG. 14 is an enlarged plan view of pixel array 10A with first insulating layer 51 (see FIG. 15 and FIG. 16), second insulating layer 57 (see FIG. 15 and FIG. 16), optical waveguide 52 (see FIG. 15 and FIG. 16), wiring 53 (see FIG. 15 and FIG. 16), and micro lens 54 (see FIG. 15 and FIG. 16) deleted from pixel array 10A. In the following, with respect to pixel array 10A, since the same components as pixel array 10 have already been described, the same reference numerals are given to omit the detailed description thereof, and the difference from pixel array 10 will be mainly described.

As shown in FIG. 14 to FIG. 16, each pixel 11A included in pixel array 10A is configured by including first semiconductor layer 12, second semiconductor layer 13, first semiconductor region 14, first separator 16A, second separator 17A, semiconductor substrate 18, first conductivity type well 56, second conductivity type well 55, first insulating layer 51, second insulating layer 57, wiring 53, optical waveguide 52, and micro lens 54. Then, each pixel 11A includes photodiode region 41 in which an avalanche photodiode is formed and circuit region 42 in which a pixel circuit is formed.

First conductivity type well 56 is a well of a first conductivity type (here, for example, P type) formed in second semiconductor layer 13. First conductivity type well 56 is formed, for example, by injecting first conductivity type impurity (for example, boron) ions accelerated at a voltage in a desired range from the surface of second semiconductor layer 13. Among the transistors included in the pixel circuit, a transistor of the second conductivity type is formed in first conductivity type well 56.

Second conductivity type well 55 is a well of a second conductivity type (here, for example, N type) formed in first conductivity type well 56. Second conductivity type well 55 is formed, for example, by injecting second conductivity type impurity (for example, arsenic) ions accelerated by a voltage in a desired range from the surface of first conductivity type well 56. Second conductivity type well 55 electrically separates first conductivity type well 56 from first semiconductor layer 12 and second semiconductor layer 13.

First insulating layer 51 is an insulating layer located above second semiconductor layer 13. First insulating layer 51 comprises, for example, silicon oxide or the like, and is formed by a CVD (Chemical Vapor Deposition) method.

Second insulating layer 57 is an insulating layer that is located in first insulating layer 51 and insulates between wirings 53. The second insulating layer comprises, for example, silicon nitride or the like, and is formed by a CVD method.

Wiring 53 is a metal wiring located in first insulating layer 51 and second insulating layer 57. Wiring 53 transmits a signal used in third semiconductor chip 300. Wiring 53 comprises, for example, aluminum, copper, or the like, and is formed by, for example, the dual damascene method.

Micro lens 54 is disposed above first insulating layer 51, that is, on the surface of third semiconductor chip 300, and focuses light incident from the outside of third semiconductor chip 300.

Optical waveguide 52 is located in first insulating layer 51 and guides the light focused by micro lens 54 to a desired region of photodiode region 41.

First separator 16A is the same as first separator 16 according to Embodiment 1 except that the shape thereof is different. First separator 16A electrically separates photodiode regions 41 of pixels 11A adjacent to each other. First separator 16A also electrically separates photodiode region 41 from circuit region 42 within one pixel 11A.

Second separator 17A is the same as second separator 17 according to Embodiment 1 except that the shape thereof is different. Second separator 17A overlaps at least part of multiplication region 15 and overlaps entire circuit region 42 in a plan view of pixel array 10A. The shape of second separator 17A is formed such that the lower portion of first semiconductor region 14 in photodiode region 41 has substantially the same configuration as the lower portion of first semiconductor region 14 in pixel 11 according to Embodiment 1.

### 4-2. Consideration

According to photodetector 1A having the above configuration, photodiode region 41 functions in the same manner as pixel 11 according to Embodiment 1. Therefore, according to photodetector 1A, the same effect as that of photodetector 1 according to Embodiment 1 can be obtained.

In addition, second separator 17A overlaps entire circuit region 42 in a plan view of pixel array 10A. For this reason, the electric charge generated by the photoelectric effect in first semiconductor layer 12 is suppressed from being heat diffused into circuit region 42. With this, the invasion of the electric charge generated by the photoelectric effect in first semiconductor layer 12 into the pixel circuit formed in circuit region 42 is suppressed. Therefore, according to photodetector 1A, the detection accuracy at the time when photon detection is performed can be improved.

### Variation 3

Hereinafter, the photodetector according to Variation 3, which is configured by changing a part of the configuration from photodetector 1A according to Embodiment 2, will be described.

### 5-1. Configuration

The photodetector according to Variation 3 is configured by changing second separator 17A from photodetector 1A to the second separator according to Variation 3. Then, along with this change, pixel 11A is changed to the pixel according to Variation 3, and pixel array 10A is changed to the pixel array according to Variation 3.

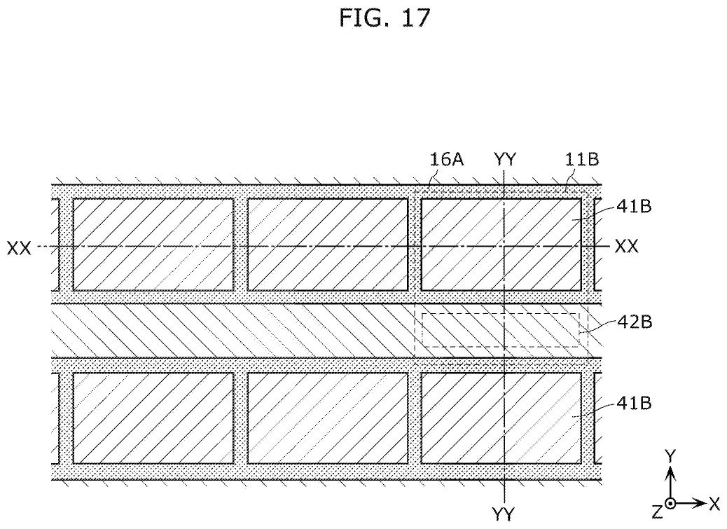

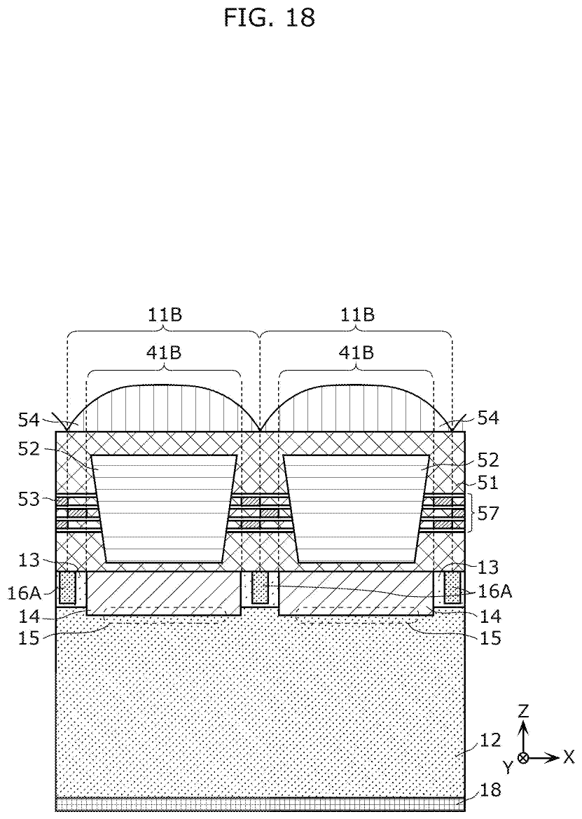

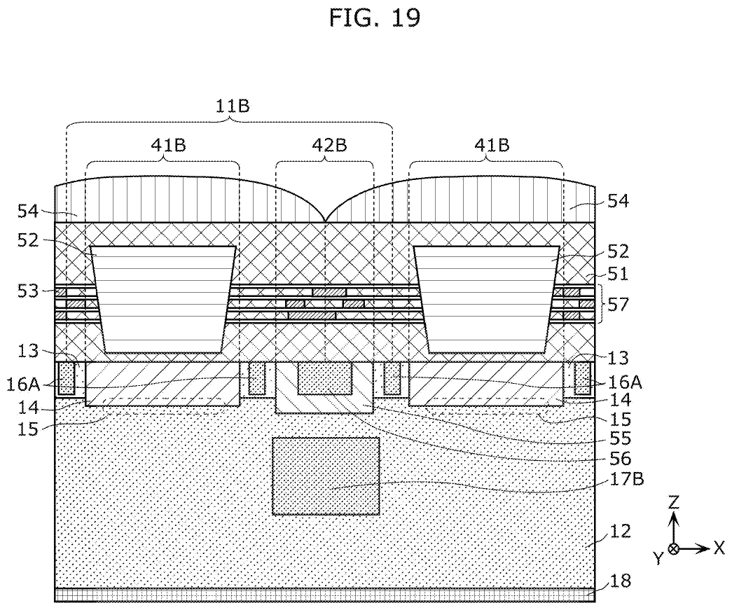

FIG. 17 is an enlarged plan view of the pixel array according to Variation 3. FIG. 18 is an enlarged cross-sectional view of the pixel array according to Variation 3 in the case where the pixel array according to Variation 3 is cut along the XX-XX line in FIG. 17. FIG. 19 is an enlarged cross-sectional view of the pixel array according to Variation 3 in the case where the pixel array according to Variation 3 is cut along the YY-YY line of FIG. 17. Here, in order to make the drawing easier to see, FIG. 17 is an enlarged plan view of pixel array 10 according to Variation 3 with first insulating layer 51, optical waveguide 52, wiring 53, micro lens 54, and second insulating layer 57 deleted from the pixel array according to Variation 3. In the following, regarding the photodetector according to Variation 3, the same components as photodetector 1A have already been described, so that the same reference numerals are given to omit the detailed description thereof, and the differences from photodetector 1A will be mainly described.

As shown in FIG. 17 to FIG. 19, each pixel 11B included in the pixel array according to Variation 3 is configured by changing second separator 17A to second separator 17B from pixel 11A according to Embodiment 2. Then, along with this change, photodiode region 41 is changed to photodiode region 41B, and circuit region 42 is changed to circuit region 42B.

Second separator 17B is the same as second separator 17A according to Embodiment 2 except that the shape thereof is different. Second separator 17B overlaps at least part of circuit region 42B and does not overlap multiplication region 15 in a plan view of the pixel array according to Variation 3. Here, as shown in FIG. 17, second separator 17B may overlap entire circuit region 42 in a plan view of the pixel array according to Variation 3.

### 5-2. Consideration

In the photodetector according to Variation 3 of the above configuration, second separator 17B overlaps at least part of circuit region 42B in a plan view of the pixel array according to Variation 3. For this reason, the electric charge generated by the photoelectric effect in first semiconductor layer 12 is suppressed from being heat diffused into circuit region 42B. With this, the invasion of the electric charge generated by the photoelectric effect in first semiconductor layer 12 into the pixel circuit formed in circuit region 42B is suppressed. Therefore, according to the photodetector according to Variation 3, the detection accuracy when performing photon detection can be improved.

### Variation 4

Hereinafter, the photodetector according to Variation 4 which is configured by modifying a part of the configuration from the photodetector according to Variation 3 will be described.

### 6-1. Configuration

The photodetector according to Variation 4 is configured by changing second separator 17Y according to Variation 3 to the second separator according to Variation 4 from the photodetector according to Variation 3. Then, along with this change, the pixels according to Variation 3 are changed to the pixels according to Variation 4, and the pixel array according to Variation 3 is changed to the pixel array according to Variation 4.

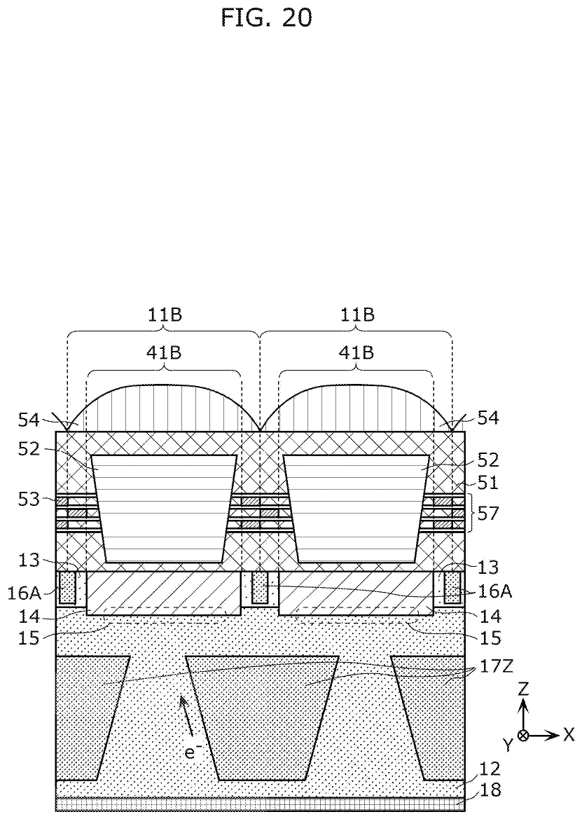

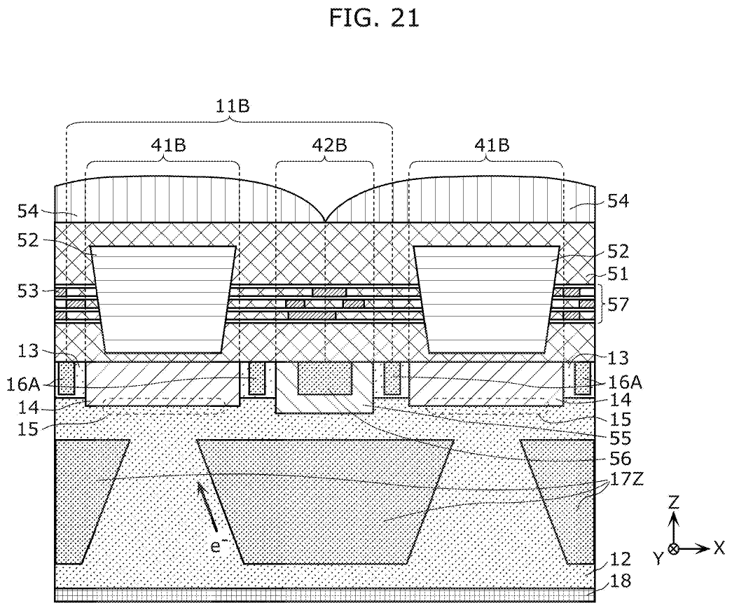

FIG. 20 is an enlarged cross-sectional view of the pixel array according to Variation 4 when the pixel array according to Variation 4 is cut along the line corresponding to the XX-XX line in FIG. 17. FIG. 21 is an enlarged cross-sectional view of the pixel array according to Variation 4 when the pixel array according to Variation 4 is cut along the line corresponding to the YY-YY line of FIG. 17. In the following, with respect to the photodetector according to Variation 4, since the same components as the photodetector according to Variation 3 have already been described, the same reference numerals are given to omit the detailed description thereof, and the difference from the photodetector according to Variation 3 will be mainly described.

As shown in FIG. 20 and FIG. 21, each pixel according to Variation 4 included in the pixel array according to Variation 4 is configured by changing second separator 17Y to second separator 17Z from pixel 11B according to Variation 3.

Second separator 17Z is configured by changing the shape thereof from that of second separator 17B. More specifically, second separator 17Z has a cross section parallel to the pixel array according to Variation 4, extending from the lower side to the upper side.

### 6-2. Consideration

According to the photodetector according to Variation 4 of the above configuration, the detection efficiency is not lowered even if effective multiplication region 15 is narrowed. With this, the photodiode can be made small.

In addition, according to the photodetector according to Variation 4 of the above configuration, by widening the upper side of second separator 17Z, the diffusion of the signal charges to other than the photodiode can be suppressed, and by narrowing the lower side of second separation portion 17Z, the diffusion of signal charges to adjacent pixels can be suppressed.

### Supplement

As described above, as examples of the technique disclosed in the present application, Embodiments 1 to 2 and Variations 1 to 4 have been described. However, the technique according to the present disclosure is not limited thereto, and can be applied to embodiments or variations in which modifications, replacements, additions, omissions, or the like are appropriately made without departing from the spirit of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The photodetector according to the present disclosure can be widely used as a device for detecting light and the like.

1. A photodetector, comprising:
a pixel array in which a plurality of pixels are arranged in an array,
wherein each of the plurality of pixels includes:
a first semiconductor layer of a first conductivity type;
a second semiconductor layer of the first conductivity type located above the first semiconductor layer and having an impurity concentration lower than an impurity concentration of the first semiconductor layer; and
a first semiconductor region of a second conductivity type disposed in the second semiconductor layer and joined to the first semiconductor layer, the second conductivity type being different from the first conductivity type,
the first semiconductor layer and the first semiconductor region constitute a multiplication region in which a charge is multiplied by avalanche multiplication, and
the pixel array includes a first separator of the first conductivity type disposed in the second semiconductor layer and a second separator of the first conductivity type disposed in the first semiconductor layer.

2. The photodetector according to claim 1,
wherein the second separator has an impurity concentration higher than an impurity concentration of a region of the first semiconductor layer which is of a same depth as the second separator and where the second separator is not disposed.

3. The photodetector according to claim 1,
wherein, in a plan view of the pixel array, the second separator overlaps at least part of the first semiconductor region in each of the plurality of pixels.

4. The photodetector according to claim 3,
wherein, in a plan view of the pixel array, the second separator does not overlap at least part of a uniform electric field region included in the first semiconductor region in each of the plurality of pixels, the uniform electric field region being a region in which an electric field is uniform.

5. The photodetector according to claim 1,
wherein an impurity concentration of the first semiconductor layer is high on an upper side where the multiplication region is included, and an impurity concentration on a lower side of the first semiconductor layer is lower than or equal to the impurity concentration on the upper side.

6. The photodetector according to claim 1,
wherein the impurity concentration of the first semiconductor layer increases from an upper side to a lower side of the first semiconductor layer.

7. The photodetector according to claim 1,
wherein the pixel includes a circuit region disposed in the second semiconductor layer, the circuit region including one or more transistors, and
the second separator overlaps at least part of the circuit region in a plan view of the pixel array.

8. The photodetector according to claim 1,
wherein the second separator has a cross section parallel to the pixel array extending from an upper side to a lower side of the first semiconductor layer.

9. The photodetector according to claim 1,
wherein the second separator has a cross section parallel to the pixel array extending from a lower side to an upper side of the first semiconductor layer.
